(19) United States
(12) Patent Application Publication
(10) Pub. No.: US 2026/0204871 A1
(43) Pub. Date: Jul. 16, 2026

(54) LIDAR AND GAIN DEVICE THEREOF, AND LASER

(71) Applicant: Lunor Technology Co., Ltd., Beijing (CN)

(72) Inventors: Yihui LIU, Beijing (CN); Yang XU, Beijing (CN); Yongqiang DENG, Beijing (CN)

(73) Assignee: Lunor Technology Co., Ltd., Beijing (CN)

(21) Appl. No.: 19/444,224

(22) Filed: Jan. 9, 2026

(30) Foreign Application Priority Data
Jan. 10, 2025 (CN) 202510045591.2

(51) Int. Cl. H01S 5/10; G01S 7/481; H01S 3/08018; H01S 5/14

(52) U.S. Cl. CPC H01S 5/1014; G01S 7/4814; H01S 3/08018; H01S 5/14

(57) ABSTRACT

The present application discloses a LiDAR and a gain device thereof, and a laser. This device relates to the field of LiDAR, including: an active region and n waveguide segments provided separately and connected in series on one side of the active region, where different bias currents are applied to the n waveguide segments, and current modulation signals are applied to at least one waveguide segment except for waveguide segments at two ends of the n waveguide segments, to adjust effective width-spectrum gain of the active region, where n is an integer greater than or equal to 3. The present application solves the technical problems of severe performance degradation of a gain device in the LiDAR at high temperatures and poor modulation performance of the gain device in related arts.

### CROSS-REFERENCE TO RELATED APPLICATION

This application claims priority to Chinese Patent Application No. 202510045591.2, filed on January 10, 2025, which is hereby incorporated by reference in its entirety.

### TECHNICAL FIELD

The present application relates to the field of LiDAR (Light Detection And Ranging) and, specifically, to a LiDAR and a gain device thereof, and a laser.

### BACKGROUND

In the field of LiDAR, an optical system based on Frequency Modular Continuous Wave (Frequency Modulated Continuous Wave, FMCW) are highly favored due to their excellent performance in distance measurement, velocity detection, target recognition and other aspects. The FMCW technology achieves high-precision and high-resolution measurements by continuously emitting light waves with linearly changing frequencies over time, and calculating a distance to the target using the frequency difference between the received signal and the emitted signal. Therefore, in the application field of FMCW, laser sources with narrow linewidth and high coherence characteristics have become the key to determining ranging accuracy, resolution, and stability. Among them, heterogeneous device integrated lasers implemented based on external-cavity structures of silicon-based material or other heterogeneous material have become one of the most promising light source choices due to their extremely narrow linewidth and good single-mode characteristics.

A heterogeneous device integrated laser mainly consists of an active gain device and a waveguide device including a micro-ring structure. They can achieve the complete device performance through edge coupling hybrid integration, or heterogeneous integration based on bonding technology, or other methods. The gain device, as a key component in the FMCW LiDAR system, is responsible for providing continuous output wide-spectrum gain while also has fast response modulation characteristics. Therefore, the performance of the gain device directly determines the measurement capability and system stability of the heterogeneous device integrated laser in the FMCW LiDAR. Traditional gain devices suffer from severe performance degradation under an operating condition with high temperatures. At the same time, based on the mode-selection function of silicon-based waveguide devices, the consistency of performance at different lasing wavelengths is very low, and even a phenomenon that frequency modulation cannot be achieved may occur.

There is currently no effective solution proposed to address the above-mentioned problems, except for cascading multiple gain devices to alleviate them.

### SUMMARY

Embodiments of the present application provide a LiDAR and a gain device thereof, and a laser, to at least solve or improve the technical problems of severe performance degradation of the gain device of the LiDAR at high temperatures, limited wavelength coverage range of ASE (Amplified Spontaneous Emission) full width at half maximum of the gain device, and poor modulation performance of the gain device in related arts.

According to an aspect of an embodiment of the present application, a gain device of a LiDAR is provided, including: an active region and n waveguide segments provided separately and connected in series on one side of the active region, where different bias currents are applied to the n waveguide segments, and current modulation signals are applied to at least one waveguide segment except for waveguide segments at two ends of the n waveguide segments, to adjust wide-spectrum gain and dynamic response jointly generated by the active region, where n is an integer greater than or equal to 3.

Furthermore, a waveguide parameter of each waveguide segment includes at least one of following: a length of the waveguide segment, a width of the waveguide segment, curvature of the waveguide segment or a tilt angle of the waveguide segment.

Furthermore, the gain device is provided with 3 waveguide segments.

Furthermore, a light output end of the active region is an anti-reflection edge, the other end of the active region is a high-reflection edge, a reflectivity of the anti-reflection edge is lower than a reflectivity of the high-reflection edge.

Furthermore, a high resistance region is provided between any two waveguide segments, the high resistance region is used to isolate the any two waveguide segments.

Furthermore, the gain device is a single end-edge emitting device.

A laser provided in another aspect of an embodiment of the present application, includes: a gain device and an external-cavity mode-selection device, where the gain device and the external-cavity mode-selection device are butt-coupled, where the gain device is the gain device according to a respective embodiment of the present application.

According to another aspect of an embodiment of the present application, a LiDAR is also provided, including: a light source, a transceiver module, a detection module and an information processing module; where the light source is the laser according to a respective embodiment of the present application.

Furthermore, the transceiver module includes: an optical phased array antenna array, an optical switch antenna array or an arrayed waveguide grating component.

Furthermore, the light source is a light source of frequency modulated continuous wave.

In the embodiments of the present application, it uses the following methods: an active region and n waveguide segments provided separately and connected in series on one side of the active region, where different bias currents are applied to the n waveguide segments. By dividing the gain device into multiple series connected waveguide segments and applying current to different waveguide segment(s), the gain distribution in the active region can be more finely controlled, wider spectrum gain jointly generated by the active region can be achieved. Furthermore, this structure with flexible current combination can improve the performance degradation of the gain device under wide operating temperatures. By applying the current modulation signals to at least one waveguide segment except for waveguide segments at two ends of the n waveguide segments, the dynamic modulation characteristics of the gain region can be optimized. At the same time, it compensates for the modulation performance under different mode selections based on a silicon-based external-cavity device; thereby achieving the technical effect of improving the consistency of wide spectrum gain of the gain device in the LiDAR and achieving the consistency of modulation performance at a wide range of wavelength based on the gain device. Then this solves or improves the technical problems of severe performance degradation of the gain device and poor modulation performance of the gain device under larger wavelength coverage range of the LiDAR and at high temperatures in related arts.

### BRIEF DESCRIPTION OF DRAWINGS

The accompanying drawings described herein are intended to provide further understanding of the present application, and form a part of the present application. The illustrative embodiments of the present application and the description thereof are used to explain the present application, and do not constitute improper limitation to the present application. In the drawings:

FIG. 1 is a structural block diagram of a gain device of a LiDAR according to an embodiment of the present application.

FIG. 2 is a schematic structural diagram of a gain device with separate injections from three segments of electrodes according to an embodiment of the present application.

FIG. 3 is a schematic structural diagram of another gain device with separate injections from three segments of electrodes based on a heterogeneous integration solution, according to an embodiment of the present application.

### DESCRIPTION OF EMBODIMENTS

In order to enable those skilled in the art to better understand the solution of the present application, a clear and complete description of the technical solution in the embodiments of the present application will be provided in conjunction with the accompanying drawings in the below. Obviously, the described embodiments are only a part of the embodiments of the present application, not all of them. All other embodiments obtained, based on the embodiments of the present application, by those ordinary skilled in the art without creative effort should fall within the protection scope of the present application.

It should be noted that the terms "first", "second", etc. in the specification and claims of the present application as well as the above-mentioned accompanying drawings are used to distinguish similar objects, and are not necessarily used to describe a specific order or sequence. It should be understood that the terms used in this manner can be interchanged in appropriate circumstances, so that the embodiments of the present application described herein can be implemented in an order other than those illustrated or described herein. In addition, the terms "including" and "having", as well as any variations thereof, are intended to cover non-exclusive inclusions. For example, processes, methods, systems, products, or devices that contain a series of steps or units are not necessarily limited to those clearly listed steps or units, but may include other steps or units that are not clearly listed or that are inherent to these processes, methods, products, or devices.

Embodiments of the present application provide a LiDAR and a gain device thereof, and a laser, to at least solve or improve the technical problems of severe performance degradation of the gain device of the LiDAR at high temperatures, limited wavelength coverage range of ASE (Amplified Spontaneous Emission) full width at half maximum of the gain device, and poor modulation performance of the gain device in related arts.

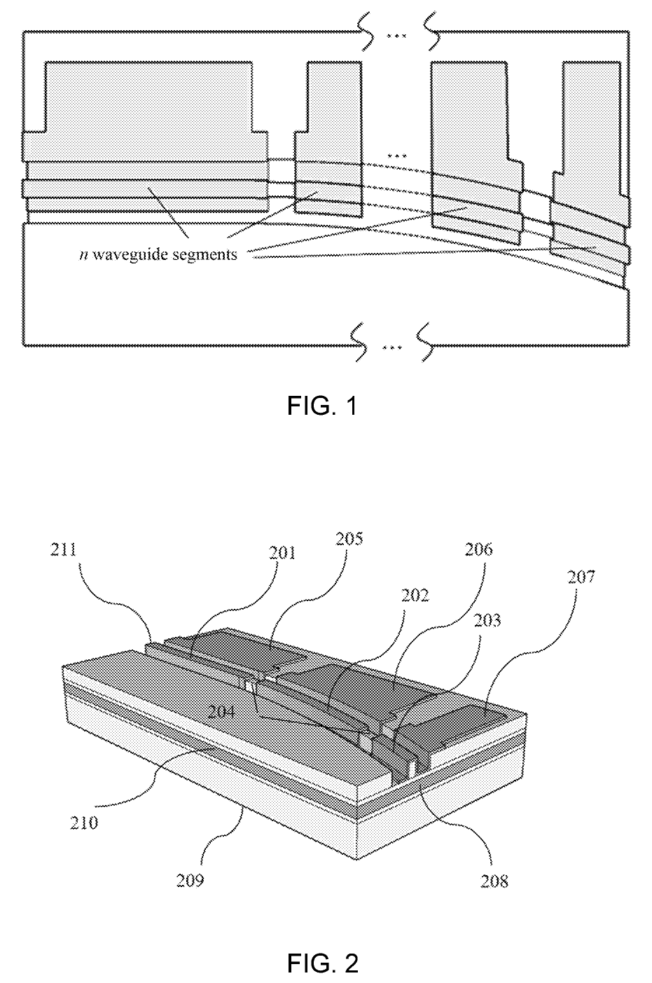

According to an embodiment of the present application, an embodiment of a gain device of a LiDAR is provided. FIG. 1 is a structural block diagram of a gain device of a LiDAR according to an embodiment of the present application. As shown in FIG. 1, the device includes:

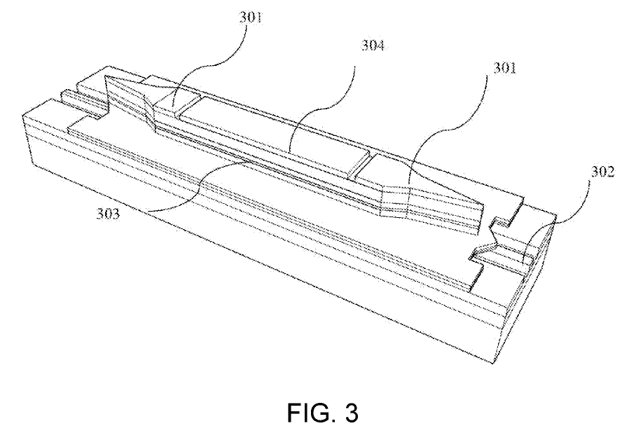

an active region and n waveguide segments provided separately and connected in series on one side of the active region, where different bias currents are applied to the n waveguide segments, and current modulation signals are applied to at least one waveguide segment except for waveguide segments at two ends of the n waveguide segments, to adjust wide-spectrum gain and dynamic response jointly generated by the active region, where n is an integer greater than or equal to 3. The specific setting location of the above-mentioned active region can be shown in FIG. 2 or FIG. 3.

The above-mentioned active region may be a region used to provide wide-spectrum gain and achieve stable frequency modulation. The above-mentioned active region may be made of semiconductor materials, and when combined current is injected into the complete device, the active region can generate wide-spectrum gain with a certain optical power, while this device can also perform optical amplification on the injected specific optical signal. The above-mentioned waveguide segments can be a structure that guides light waves to propagate inside the device. The above-mentioned waveguide segments can be made of high refractive index material surrounded by low refractive index material, forming a channel through which light waves can propagate along a specific path. The above-mentioned bias current may refer to a constant current provided to the active region when there is no signal (i.e. modulation signal) input, to ensure that the active region is in a suitable excited state and generate stable wide-spectrum gain. The above-mentioned current modulation signal may be an additional current variation applied to some waveguide segments of the gain device, used to modulate the output frequency or power of the laser. The above-mentioned effective wide-spectrum gain may refer to the frequency range within which the gain device can effectively amplify the optical signal, this range determines the maximum wavelength range that the laser can be tuned to. By adjusting the current or the current combination in the waveguide segments, the optical characteristics of the active region can be altered, thereby altering the effective wide-spectrum gain and enabling the laser to have stable optical amplification over a larger frequency range.

In an embodiment, the active region of the gain device of the LiDAR and at least three (n ≥ 3) separate waveguide segments connected in series with the active region can enhance the modulation bandwidth and frequency stability of the gain device, by applying specific bias currents to different waveguide segments and applying current modulation signals to at least one waveguide segment in the middle. In this embodiment, by precisely controlling the current modulation of the waveguide segment(s) in the middle, the stability of the gain spectrum in frequency tuning can be effectively improved, thereby enhancing the modulation bandwidth without sacrificing frequency linearity and stability. For an FMCW LiDAR system that requires high repetition rate and high real-time performance, this means higher angular resolution and finer ranging capability. In addition, by adjusting the current modulation of the waveguide segment(s) in the middle, a wider dynamic tuning range and better linear modulation characteristics can be achieved, thereby improving the ranging accuracy and increasing dynamic range of the LiDAR system. Compared to modulation with a single waveguide segment, segmented modulation can better overcome the problems of nonlinear modulation and intensity modulation of frequency, and improve the efficiency and accuracy of signal processing.

In the embodiment of the present application, it uses the following method: an active region is provided and n waveguide segments are provided separately and connected in series on one side of the active region (in other words, n waveguide segments are provided separately and connected in series in the gain active region structure), where different bias currents are applied to the n waveguide segments, and current modulation signals are applied to at least one waveguide segment except for waveguide segments at two ends of the n waveguide segments, to adjust wide-spectrum gain jointly generated by the active region. By dividing the gain device into multiple series connected waveguide segments and modulating the current of the waveguide segment(s) in the middle part, the gain distribution in the active region can be more finely controlled. By applying current to different waveguide segments, the dynamic modulation characteristics of the gain region can be optimized, this not only increases the spectrum line width of ASE full width at half maximum of the gain device, but also improves the performance degradation of the gain device under wide operating temperatures. At the same time, it compensates for the modulation performance under different mode selections based on a silicon-based external-cavity device; thereby achieving the technical effect of improving the consistency of wide spectrum gain of the gain device in the LiDAR and achieving the consistency of modulation performance at a wide range of wavelength based on the gain device. Then this solves the technical problems of severe performance degradation of the gain device at high temperatures and poor modulation performance of the gain device under larger wavelength coverage range of the LiDAR in related arts.

Furthermore, the coupling method between the active gain device and the heterogeneous external-cavity waveguide device is not limited to a hybrid integration method based on butt-coupling or a heterogeneous integration method based on bonding, or other methods. Among them, the gain device in the hybrid integration requires reasonable coating on its edges, with additional anti-reflection coating on the butting edge to improve coupling efficiency. In the heterogeneous integration based on bonding, the gain device needs to achieve light transiency from the gain device to the external-cavity waveguide device through the taper waveguides.

Furthermore, a waveguide parameter of each waveguide segment (for example, one of the waveguide segments 201, 202 and 203 in FIG. 2) includes at least one of following: a length of the waveguide segment, a width of the waveguide segment, curvature of the waveguide segment or a tilt angle of the waveguide segment. In an implementation, a waveguide parameter of a waveguide segment (for example, the straight waveguide segment 304) includes at least one of following: a length of the waveguide segment or a width of the waveguide segment; a waveguide parameter of a waveguide segment (for example, the taper waveguide segment 301) includes at least one of following: a length of the waveguide segment, a width o of the waveguide segment, and width variation of the waveguide segment.

The above waveguide parameters may be physical properties considered in the design and analysis of optical waveguides, these properties directly affect the propagation characteristics of light waves within the waveguides.

In an embodiment, fine control and performance improvement of laser signals are achieved by designing waveguide parameters for the n waveguide segments, including structural parameters such as a length, a width, curvature or a tilt angle of each waveguide segment in FIG. 2; or, a length or a width of a straight waveguide segment in FIG. 3, a length, a width, or a width variation of a taper waveguide segment in FIG. 3, and material parameters such as material layer composition and a thickness. The adjustment and optimization of these parameters enable the gain device to maintain good wide-spectrum gain over a wider range of operating temperatures, while achieving the optimization of modulation characteristics through flexible electrical injection. In this embodiment, by adjusting the length of the waveguide segment(s) in the middle or the length of the waveguide segment(s) at other positions, the electrical injection level of the entire waveguide segments can be changed, thereby affecting the density distribution of the gain spectrum of the wide-spectrum gain of the active region. In high-temperature environments, the density distribution of overall carriers can be optimized by adjusting the electrical injection level of the gain device, thereby improving the performance degradation of the gain device at high temperatures. In addition, by reasonably designing the length ratio of the waveguide segment(s) in the middle and the tilt angle and curvature between multiple segments, the flatness of the overall effective wide-spectrum gain of the device can be improved, thereby providing a wider wavelength tuning range for passive silicon-based waveguides. At the same time, in combination with the flexible adjustment of multi-segments electrical injection, the performance consistency under different lasing wavelengths can be significantly improved. On this basis, by the manner of introducing modulation signals into a part of the waveguide segments, the overall modulation characteristics of the external-cavity laser can be improved, and the detection accuracy and signal-to-noise ratio of the LiDAR can be enhanced. The curvature and the tilt angle of waveguide can affect the entire distribution of the gain spectrum of the device. In this embodiment, appropriately introducing the curvature of waveguide can reduce the overall intracavitary reflection of the external-cavity laser, while introducing the curvature can suppress a high-order mode inside the device. This will be beneficial for the modulation characteristics of the effective gain width in the active region, which can not only improve the linearity and modulation characteristics of the signal, but also reduce the intensity modulation effect caused by frequency nonlinear modulation at the same time. This improves the linearity of frequency modulation, and thus improves the frequency drift problem/error caused by the nonlinearity of frequency modulation. The Taper structure is only applied in the gain active device structure in the heterogeneous integrated device, and its structural parameters such as the length and the etching depth directly affect the light transiency effect. Reasonable structural design combined with the transient segment waveguide structure of the external-cavity waveguide device can greatly reduce coupling losses, improve the photoelectric efficiency and performance under a wide operating temperature of actual devices.

Furthermore, the gain device is provided with 3 waveguide segments.

In an embodiment, a three-segment design of gain device containing three waveguide segments can be used to achieve precise control of the effective width-spectrum gain generated jointly by the active region. FIG. 2 is a schematic structural diagram of a gain device with separate injections from three segments of electrodes according to an embodiment of the present application. As shown in FIG. 2, the structure includes: an active region 210 including a gain medium, a waveguide segment 201, a waveguide segment 202, a waveguide segment 203, a high resistance region 204, a light output edge 208, and a high-reflection edge 211. Among them, a positive electrode corresponding to the waveguide segment 201 is 205, a positive electrode corresponding to the waveguide segment 202 is 206, a positive electrode corresponding to the waveguide segment 203 is 207, and all positive electrodes correspond to a common negative electrode 209. It can be understood that during operation of the gain device, corresponding bias currents and/or current modulation signals are applied to the above-mentioned gain device respectively through electrodes matched with respective waveguide segments. For example, a current modulation signal can be applied to the waveguide segment(s) in the middle to achieve fast and linear modulation of the effective gain width of the active region. Due to the stable power output brought by two waveguide segments (as wide-spectrum gain) having fixed bias current in this design, dynamic modulation of the waveguide segment(s) in the middle can not only enhance the modulation bandwidth, but also maintain the repeatability and stability of the modulation characteristics. In addition, within a wide range of operating temperatures, the design of three waveguide segments can compensate for the performance degradation of wide-spectrum gain at high temperatures by reasonably allocating the electrical injection level. This design ensures the reliability of the LiDAR system under the condition of wide operating temperatures.

As shown in FIG. 2, the structure, along a waveguide direction (for example, a direction horizontally along the waveguide segments 201, 202 and 203), includes: three waveguide structures; and, the structure, along a vertical direction (for example, a direction perpendicular to the waveguide direction or to the three waveguide segments 201, 202 and 203), includes: n waveguide segments (for example, the waveguide segments 201, 202 and 203) which function to provide confinement and guidance of the light, an active region 210 containing gain material, other multiple light-confinement layers matching these waveguide segments and the active region 210, and other necessary metal layers required for the device, etc. Among them, the three waveguide structures may be called as a first waveguide structure, a second waveguide structure and a third waveguide structure; the first waveguide structure includes the waveguide segment 201 and gain material of a section corresponding to the waveguide segment 201, the second waveguide structure includes the waveguide segment 202 and gain material of a section of the active region 210 corresponding to the waveguide segment 202, the third waveguide structure includes the waveguide segment 203 and gain material of a section of the active region 210 corresponding to the waveguide segment 203. In other words, the waveguide segment 201 and the gain material of the section of the active region 210 corresponding to the waveguide segment 201 form the first waveguide structure; the waveguide segment 202 and the gain material of the section of the active region 210 corresponding to the waveguide segment 202 form the second waveguide structure; and the waveguide segment 203 and the gain material of the section of the active region 210 corresponding to the waveguide segment 203 form the third waveguide structure.

Furthermore, a light output end of the active region is an anti-reflection edge, the other end of the active region is a high-reflection edge, a reflectivity of the anti-reflection edge is lower than a reflectivity of the high-reflection edge.

The above-mentioned high-reflection edge may refer to an edge where an optical signal has a higher reflectivity in the gain device. Coating materials with a high reflectivity can be used for the high-reflection edge, to ensure that the optical signal resonates within the laser cavity and achieves multiple optical amplifications. The above-mentioned anti-reflection edge may be an edge that reduces the reflection of the optical signal at this edge. Anti-reflective coating can be used for the anti-reflection edge, to reduce energy loss caused by reflection when the optical signal is emitted.

In an embodiment, a light output end of the active region is designed as an anti-reflection edge, the other end of the active region is a high-reflection edge, a reflectivity of the anti-reflection edge is lower than a reflectivity of the high-reflection edge. With the light output edge 208 and the high-reflection edge 211 in the gain device as shown in FIG. 2, this design enables the high-reflection edge to effectively reflect the optical signal(s) back to the interior of the waveguide(s), maintain the resonance of the light in the waveguide(s), thereby achieving net gain superposition of the optical signal(s). While the anti-reflection edge allows the optical signal(s) to be output to an external optical system with minimal loss. In addition, due to the edge coupling between the gain device in the external-cavity laser and the silicon-based waveguide device, the coupling transmission of light from the active gain medium to the passive silicon-based waveguide is achieved. The anti-reflection coating of the gain device can improve the coupling efficiency of the two, and reduce light reflection effect between the edges for edge coupling, thereby improving the mode characteristics of the external-cavity laser, enhancing the signal-to-noise ratio of the FMCW LiDAR system, and improving the accuracy and reliability of the measurement.

In an embodiment, based on the heterogeneous integration solution, a three-segment gain device design including three waveguide segments can be adopted, to enhance the wavelength coverage range of the gain device, meanwhile, improve the high-temperature characteristics of the integrated device. FIG. 3 is a schematic structural diagram of another gain device with separate injections from three segments of electrodes based on a heterogeneous integration solution and a heterogeneous passive waveguide segment 302 below the gain device, according to an embodiment of the present application. As shown in FIG. 3, the structure, along a waveguide direction (for example, a direction horizontally along the two taper waveguide segments 301 and one straight waveguide segment 304), includes: one straight waveguide structure and two taper waveguide structures; and, the structure, along a vertical direction (a direction perpendicular to the waveguide direction or to these three waveguide segments), includes: n waveguide segments (for example, the two taper waveguide segments 301 and one straight waveguide segment 304) which function to provide confinement and guidance of the light, an active region 303 containing gain material, a passive waveguide structure, other multiple light-confinement layers matching these waveguide segments and the active region 303, and other necessary metal layers required for the device, etc. Among them, the straight waveguide structure includes the straight waveguide segment 304 and gain material of a section of the active region 303 corresponding to the straight waveguide segment 304, one of the two taper waveguide structures includes one taper waveguide segment 301 of the two taper waveguide segments and gain material of a section of the active region 303 corresponding to the one taper waveguide segment 301. In other words, the straight waveguide segment 304 and the gain material of the section of the active region 303 corresponding to the straight waveguide segment 304 form the straight waveguide structure; one taper waveguide segment 301 of the two taper waveguide segments and the gain material of the section of the active region 303 corresponding to the one taper waveguide segment 301 form one taper waveguide structure, two taper waveguide segments 301 respectively correspond to two taper waveguide structures. The straight waveguide structure and the two taper waveguide structures form a gain structure, also called as an active waveguide structure. The passive waveguide structure includes a passive heterogeneous waveguide segment 302 and matches the gain structure/active waveguide structure described above; accordingly, the passive heterogeneous waveguide segment 302 also matches the gain structure/active waveguide structure described above. Through the reasonable design of the waveguide structures with different materials (i.e. the active waveguide structure and the passive waveguide structure) described above, light transiency effect with extremely low optical loss can be achieved. The lasing light signal of the gain device is coupled into the heterogeneous passive waveguide structure in the below. The gain device uses a three-segment electrical injection combination, which can effectively enhance the wavelength coverage range of its wide-spectrum gain and enhance the wavelength tuning range of the passive waveguide device. At the same time, using the electrical injection of three-segment current combination can improve the degradation of gain spectrum of the device at high temperatures and improve the overall high-temperature characteristics of the device. In addition, one of the segments can also be selected to achieve frequency modulation of the signal, which not only enhances the modulation bandwidth but also improves the intensity modulation phenomenon caused by frequency modulation in the device. At this moment, the device can achieve the transient wave coupling between the active structure and the passive structure, without the extra need for edge coating. Among them, the straight waveguide structure primarily functions to provide optical gain, while the taper waveguide structures not only provide this function of optical gain but also primarily function to provide transient wave optical coupling; the passive waveguide structure or the passive heterogeneous waveguide segment 302 in the below mainly plays the role of supporting transient wave, in addition, serves other comprehensive functions such as mode maintenance and mode spot matching.

Furthermore, a high resistance region is provided between any two waveguide segments, the high resistance region is used to isolate the any two waveguide segments.

The above-mentioned high resistance region may refer to a region or structure with high resistance characteristics provided between two waveguide segments, such as the two high resistance regions 204 in the gain device shown in FIG. 2. The main function of the high resistance region is electrical isolation, ensuring that the current injection and the optical signal(s) do not cause unnecessary crosstalk and interference among respective waveguide segments, thereby achieving independent current control and signal modulation for each waveguide segment.

In an embodiment, current control and signal modulation among respective waveguide segments need to be highly independent, to avoid mutual interference of current or optical signal(s) among different waveguide segments, ensuring that the functional characteristics of each waveguide segment can be individually and accurately controlled. Therefore, a high resistance region is provided between any two waveguide segments, which serves as electrical isolation to achieve independent and precise current injection and signal control for each waveguide segment. In this embodiment, the presence of high resistance regions improves the independence of current injection, allowing that a different current control signal is applied to a respective waveguide segment without being affected by other waveguide segments. This is particularly important for applications that require precise control of frequency modulation characteristics in the FMCW LiDAR, which can achieve finer current modulation and improve the accuracy of frequency modulation.

Furthermore, the gain device is a single end-edge emitting device. In an implementation, the gain device is a single end-edge emitting device in a hybrid integration solution, and can be coupled in a single-edge transient wave within a heterogeneous integrated structure.

In an embodiment, the design of the single end-edge emitting device means that optical signals are emitted only from one face of the gain device, rather than from both ends or from other directions. The single end-edge emitting device can uses a structure of optical cavity and waveguide, to achieve high efficiency of optical signal output and precise steering control of light beams. In this embodiment, the design of single end-edge emission assists in improving the power efficiency of the gain device while reducing the resonance effect caused by reflection. By reducing the resonance effect of light inside the device, the edge mode of the external-cavity laser can be greatly reduced, and the single-mode characteristics of the selected lasing mode can be improved. This has a positive impact on the high-precision ranging of FMCW LiDAR systems.

The above structure of the device (as shown in FIG. 2 or FIG. 3) achieves light source with stable wide-spectrum gain or optical amplification through the joint light confinement in the vertical direction and the waveguide direction.

A laser provided in another aspect of an embodiment of the present application, includes: a gain device and an external-cavity mode-selection device, where the gain device and the external-cavity mode-selection device are butt-coupled, and the gain device is the gain device according to a respective embodiment of the present application. In an implementation, the gain device and the external-cavity mode-selection device can implement hybrid integration through butt-coupling or implement heterogeneous device integration through heterogeneous bonding and transient wave coupling.

The above-mentioned external-cavity mode-selection device can be a component used for precisely controlling the laser modes. The device completes mode-selection through the structural design of silicon-based waveguides, and uses the optical feedback mechanism inside the cavity to select and stabilize the laser mode, thereby achieving fine control of laser frequency and ensuring that the lasing mode of the device has good narrow linewidth characteristics.

In an embodiment, the above-mentioned laser mainly consists of the gain device and the external-cavity mode-selection device, which are connected together through precise butt-coupling (to achieve the hybrid integration), or through coupling based on heterogeneous bonding or transient wave coupling (to achieve the heterogeneous integration), to form an efficient and stable integrated device. Among them, the gain device is responsible for generating wide-spectrum gain with high power spectral density, while the external-cavity mode-selection device is used to select the laser mode, to improve the linewidth and frequency stability of the optical signal(s), ensuring accurate modulation and measurement of the laser signal in the FMCW radar system. In this embodiment, efficient gain and precise frequency modulation of optical signal(s) can be achieved by the butt-coupling of the gain device with the external-cavity mode-selection device. The gain medium in the gain device generates the wide-spectrum gain with high power spectral density under the drive of current injection, while the external-cavity mode-selection device precisely controls, through its internal micro-ring structure, grating structure or other reflecting mirror structure, the mode of the optical signal(s), to improve the linearity and stability of frequency modulation.

According to another aspect of an embodiment of the present application, a LiDAR is also provided, including: a light source, a transceiver module, a detection module and an information processing module; where the light source is the laser according to a respective embodiment of the present application.

The above-mentioned light source may be a device responsible for generating a laser signal for ranging, for example, the above-mentioned light source may be, but not limited to, a laser in the embodiments of the present application. The above-mentioned transceiver module may be a module responsible for emission and reception of the laser signal. The above-mentioned detection module may be a module, which consists of a photo detector and is used to convert the captured optical signal into an electrical signal. The above-mentioned information processing module may be a module responsible for processing and analyzing the electrical signal obtained from the detection module.

In an embodiment, the above-mentioned LiDAR mainly consists of the light source, the transceiver module, the detection module and the information processing module. Among them, the light source section may use a laser in the embodiments of the present application, and the design core of the laser lies in the butt-coupling of the gain device and the external-cavity mode-selection device. Through the three-segment structure of the gain device, multiple electrodes are flexibly combined to achieve overall electrical injection and provide a wide-spectrum gain that meets the requirements of external cavity mode selection, thereby achieving high power, narrow linewidth, wide tuning range, and good frequency stability. This design ensures the linearity and consistency of the laser signal during dynamic modulation, which is the key to achieving an FMCW LiDAR with high-performance. The transceiver module is responsible for the transmission and reception of the laser signal, including the emission, guidance, focusing of the light beam(s), as well as the collection and pre-processing of the received light beam(s). Since the laser signal with high-quality can be provided by the laser in the embodiments of the present application, the performance of the transceiver module is improved, that enables more effective transmission and reception of light beams. Even in long distance, targets with a low reflectivity or harsh environmental conditions, good signal strength and signal-to-noise ratio can also be maintained, thereby improving the measurement range and reliability of the LiDAR. The detection module uses a beam splitter to split the received beam into a reference light beam and a measurement light beam. Through interferometric measurement technology, the frequency difference between the two beams is accurately detected, and the distance and velocity of the target are further calculated. The laser signal output by the laser in the embodiments of the present application has high frequency stability and excellent linearity, which assists in improving the measurement accuracy and sensitivity of the detection module, achieving ranging capability of longer distance and higher accuracy. At the same time, the motion state of the target is also detected more accurately. The information processing module is responsible for processing and analyzing the signals output by the detection module, including signal demodulation, data processing, target recognition and localization, etc. Due to the laser signal of the laser in the embodiments of the present application has high quality and good frequency modulation characteristics, the information processing module can simplify complexity, reduce signal processing and correction requirements, and improve processing speed and accuracy. In addition, the use of the laser signal with narrow linewidth assists in improving the ability of identifying Doppler frequency shifts of the system and improving the accuracy of identifying and tracking moving targets.

Furthermore, the transceiver module includes: an optical phased array antenna array, an optical switch antenna array or an arrayed waveguide grating component.

The above-mentioned optical phased array antenna array may be an antenna array used for emission and reception of light beams. The above-mentioned optical switch antenna array may be an antenna array that uses optical switch technology to achieve the switch of light beam path(s). The above-mentioned arrayed waveguide grating component may be an optical component that combines waveguide technology and grating technology for achieving beam splitting, coupling, and mode selection of the optical signal.

In an embodiment, by integrating plenty of tiny units for light emitting and receiving, the optical phased array antenna array achieves precise control of a phase of the light beam, thereby enabling dynamic adjustment of the direction of emission and reception of the light beam(s) without moving physical components. This antenna array combined with the laser of the present application can improve the capability of angular resolution, scanning speed, and flexibility of the LiDAR. The optical switch antenna array uses the electro-optic effect or acousto-optic effect to quickly switch the path of the light beam(s), achieving flexible control of multiple paths of light beams. Operating in conjunction with the laser in the embodiments of the present application, the optical switch antenna array can achieve rapid scanning and switching of the light beam(s), and improve the coverage range and detection efficiency of the LiDAR. In addition, the optical switch antenna array can dynamically adjust the focusing of light beam(s) according to the feedback signal of the target, further improving the accuracy and reliability of ranging. The arrayed waveguide grating component can achieve efficiently processing of laser signals in a compact space by transmitting the optical signal(s) in the waveguide and using gratings for mode selection and frequency modulation. By butt-coupling with the laser of the present application, the arrayed waveguide grating component can optimize the laser signal into a light beam with specific directivity and frequency characteristics, improving the angular resolution and ranging accuracy of the LiDAR. In addition, the integrated design of the arrayed waveguide grating component assists in reducing system volume, and improving the integration and portability of the LiDAR system.

Furthermore, the light source is a light source of frequency modulated continuous wave. In an implementation, the light source is a multi-wavelength light source of frequency modulated continuous wave.

In an embodiment, considering that traditional light source(s) may experience frequency modulation nonlinearity or frequency jitter during frequency modulation, etc., this will directly affect the ranging accuracy of the FMCW LiDAR. The light source in this embodiment may be a light source of frequency modulated continuous wave. This light source can achieve fine control of the current modulation signal through the design of current injection in segments, significantly improving the linearity of frequency modulation, reducing frequency jitter, and thus improving the stability of the laser signal(s) of the LiDAR, thereby enhancing the accuracy of ranging.

In the above-mentioned embodiments of the present application, the description of each embodiment has its own emphasis. For the parts not described in detail in some embodiments, please refer to the relevant descriptions of other embodiments.

In the several embodiments provided in the present application, it should be understood that the disclosed technical content may be implemented in other ways. Among them, the apparatus embodiments described above are only illustrative. For example, the division of units may be a logical functional division, and there may be other division methods in actual implementation, such as multiple units or components may be combined or integrated into another system, or some features may be ignored or not executed. On the other hand, the mutual coupling or direct coupling or communication connection displayed or discussed may be indirect coupling or communication connection through some interfaces, units or modules, which may be electrical or other forms.

The units described as separate components may or may not be physically separated, and the components displayed as units may or may not be physical units, i.e. they may be located in one place or distributed across multiple units. Some or all of the units may be selected according to actual needs to achieve the purpose of these embodiments.

In addition, the various functional units in various embodiments of the present application may be integrated into one processing unit, or the various units may physically exist separately, or two or more units may be integrated into one unit. The above-mentioned integrated units may be implemented in the form of hardware or software functional units.

If the integrated units are implemented in the form of software functional units and sold or used as independent products, they may be stored in a computer-readable storage medium. Based on this understanding, the technical solution of the present application essentially, or part of the technical solution contributing to the prior art, or all or part of the technical solution, can be embodied in the form of a software product. The software product is stored in a storage medium and includes several instructions to enable a computer device (which can be a personal computer, a server, or a network device, etc.) to perform all or part of the steps of the methods described in various embodiments of the present application. The aforementioned storage medium includes various media that can store program codes, such as USB flash drives, Read-Only Memory (ROM, Read-Only Memory), Random Access Memory (RAM, Random Access Memory), portable hard drives, magnetic disks, or optical disks, etc.

Those described above are only exemplary embodiments of the present application. It should be pointed out that for those of ordinary skill in the art, several improvements and embellishments can be made without departing from the principles of the present application, and these improvements and embellishments should also be considered as falling within the protection scope of the present application.

What is claimed is:

1. A gain device, comprising: an active region and n waveguide segments provided separately and connected in series on one side of the active region, wherein different bias currents are applied to the n waveguide segments, and current modulation signals are applied to at least one waveguide segment except for waveguide segments at two ends of the n waveguide segments, to adjust wide-spectrum gain and dynamic response jointly generated by the active region, wherein n is an integer greater than or equal to 3.

2. The gain device according to claim 1, wherein a waveguide parameter of each waveguide segment comprises at least one of following: a length of the waveguide segment, a width of the waveguide segment, curvature of the waveguide segment or a tilt angle of the waveguide segment.

3. The gain device according to claim 1, wherein a light output end of the active region is an anti-reflection edge, the other end of the active region is a high-reflection edge, a reflectivity of the anti-reflection edge is lower than a reflectivity of the high-reflection edge.

4. The gain device according to claim 1, wherein a high resistance region is provided between any two waveguide segments, the high resistance region is used to isolate the any two waveguide segments.

5. The gain device according to claim 1, wherein the gain device is a single end-edge emitting device.

6. The gain device according to claim 1, wherein the n waveguide segments at least comprise one straight waveguide segment and two taper waveguide segments; the straight waveguide segment and gain material of a section of the active region corresponding to the straight waveguide segment form a straight waveguide structure; one taper waveguide segment of the two taper waveguide segments and gain material of a section of the active region corresponding to the one taper waveguide segment form a taper waveguide structure, the two taper waveguide segments respectively correspond to two taper waveguide structures.

7. The gain device according to claim 6, wherein the straight waveguide structure and the two taper waveguide structures form a gain structure, the gain structure matches a passive heterogeneous waveguide segment set below the gain device.

8. The gain device according to claim 6, wherein a waveguide parameter of the straight waveguide segment comprises at least one of following: a length of the straight waveguide segment or a width of the straight waveguide segment; a waveguide parameter of each taper waveguide segment comprises at least one of following: a length of the taper waveguide segment, a width of the taper waveguide segment, or a width variation of the taper waveguide segment.

9. A laser, comprising: a gain device and an external-cavity mode-selection device, wherein the gain device is butt-coupled to the external-cavity mode-selection device, the gain device comprises an active region and n waveguide segments provided separately and connected in series on one side of the active region, wherein different bias currents are applied to the n waveguide segments, and current modulation signals are applied to at least one waveguide segment except for waveguide segments at two ends of the n waveguide segments, to adjust wide-spectrum gain and dynamic response jointly generated by the active region, wherein n is an integer greater than or equal to 3.

10. The laser according to claim 9, wherein a waveguide parameter of each waveguide segment includes at least one of following: a length of the waveguide segment, a width of the waveguide segment, curvature of the waveguide segment or a tilt angle of the waveguide segment.

11. The laser according to claim 9, wherein a light output end of the active region is an anti-reflection edge, the other end of the active region is a high-reflection edge, a reflectivity of the anti-reflection edge is lower than a reflectivity of the high-reflection edge;
or,
the gain device is a single end-edge emitting device.

12. The laser according to claim 9, wherein a high resistance region is provided between any two waveguide segments, the high resistance region is used to isolate the any two waveguide segments.

13. The laser according to claim 9, wherein n waveguide segments at least comprise one straight waveguide segment and two taper waveguide segments; the straight waveguide segment and gain material of a section of the active region corresponding to the straight waveguide segment form a straight waveguide structure; one taper waveguide segment of the two taper waveguide segments and gain material of a section of the active region corresponding to the one taper waveguide segment form a taper waveguide structure, the two taper waveguide segments respectively correspond to two taper waveguide structures.

14. The laser according to claim 13, further comprising a passive heterogeneous waveguide segment set below the gain device, wherein the straight waveguide structure and the two taper waveguide structures form a gain structure, the gain structure matches the passive heterogeneous waveguide segment.

15. The laser according to claim 13, wherein a waveguide parameter of the straight waveguide segment comprises at least one of following: a length of the straight waveguide segment or a width of the straight waveguide segment; a waveguide parameter of each taper waveguide segment comprises at least one of following: a length of the taper waveguide segment, a width of the taper waveguide segment, or a width variation of the taper waveguide segment.

16. A LiDAR, comprising: a light source, a transceiver module, a detection module and an information processing module; wherein the light source comprises a laser comprising a gain device and an external-cavity mode-selection device, wherein the gain device is butt-coupled to the external-cavity mode-selection device; the gain device comprises an active region and n waveguide segments provided separately and connected in series on one side of the active region, wherein different bias currents are applied to the n waveguide segments, and current modulation signals are applied to at least one waveguide segment except for waveguide segments at two ends of the n waveguide segments, to adjust wide-spectrum gain and dynamic response jointly generated by the active region, wherein n is an integer greater than or equal to 3.

17. The LiDAR according to claim 16, wherein the transceiver module comprises: an optical phased array antenna array, an optical switch antenna array or an arrayed waveguide grating component.

18. The LiDAR according to claim 16, wherein the light source is a light source of frequency modulated continuous wave.

19. The LiDAR according to claim 16, wherein a light output end of the active region is an anti-reflection edge, the other end of the active region is a high-reflection edge, a reflectivity of the anti-reflection edge is lower than a reflectivity of the high-reflection edge.

20. The LiDAR according to claim 16, wherein the the n waveguide segments at least comprise one straight waveguide segment and two taper waveguide segments; the straight waveguide segment and gain material of a section of the active region corresponding to the straight waveguide segment form a straight waveguide structure; one taper waveguide segment of the two taper waveguide segments and gain material of a section of the active region corresponding to the one taper waveguide segment form a taper waveguide structure, the two taper waveguide segments respectively correspond to two taper waveguide structures.
